(19) United States
(12) Patent Application Publication
(10) Pub. No.: US 2009/0323060 A1
(43) Pub. Date: Dec. 31, 2009

(54) SPECTRAL OPTICAL SENSOR AND METHOD FOR PRODUCING AN OPTICAL SPECTRAL SENSOR

(76) Inventor: Dietmar Knipp, Bremen (DE)

Correspondence Address: COLLARD & ROE, P.C., 1077 NORTHERN BOULEVARD, ROSLYN, NY, 11576, US

(21) Appl. No.: 12/309,897

(22) PCT Filed: Jul. 31, 2007
(86) PCT No.: PCT/EP2007/006777

§ 371 Date: Mar. 31, 2009

(30) Foreign Application Priority Data
Aug. 2, 2006 (DE) 10 2006 036 003.6

(51) Int. Cl. G01J 3/447; H01L 31/0224; H01L 31/0232; H01L 31/18; G01J 4/00

(52) U.S. Cl. 356/327; 257/432; 438/59; 356/364; 977/773; 257/E31.124; 257/E31.127

(57) ABSTRACT

The invention relates to an optical spectral sensor for determining the spectral information of incident light, in particular in the visible and infrared spectral range, with at least one optoelectronic semiconductor arrangement and at least one metal film, which is surrounded by a dielectric, wherein the metal film has a periodic pattern, wherein the at least one optoelectronic semiconductor arrangement and the at least one patterned metal film are arranged in such a way that light to be detected initially passes through the patterned metal film and then impinges on the optoelectronic semiconductor arrangement, wherein the optical spectral sensor is formed in such a way that the spectral sensitivity is determined essentially by the optical properties of the patterned metal film.

The invention relates to a spectral optical sensor, to a spectrometer, which incorporates said spectral optical sensor, to the use of said spectral optical sensor for spectroscopy and to a method for producing a spectral optical sensor. The invention further relates to a spectral sensor for detecting spectral information and/or polarizations with several of the spectral optical sensors and to a method of manufacturing said spectral sensor for detecting spectral information and/or polarizations with several of the spectral optical sensors.

Known spectral optical sensors comprise a sensor element and an optical absorption filter, incident light being filtered by said absorption filter and filtered light being detected by the sensor element. As a result, color-resolved light detection is made possible. The spectral sensitivity of the sensor elements may be influenced by varying the absorption properties of the absorption filter.

The disadvantage of these known optical sensors is that each filter of such an arrangement must be manufactured separately. Further, absorption filters can only be made with certain optical properties. Narrow-band optical filters for example cannot be manufactured.

Optical sensors are further known, which consist of a sensor element and of a diffraction grating. If the gap width of a diffraction grating is less than λ/2/n, wherein λ is the wavelength of incident light and n the index of refraction in the gap area, a diffraction grating behaves like an edge filter. In this case, the diffraction grating allows passage of light having a wavelength of less than 2·d·n, wherein d is the gap width of the diffraction grating, whereas light having a wavelength of more than 2·d·n is not allowed to pass through the diffraction grating. Consequently, the diffraction grating behaves like an optical edge filter. Detection of a given wavelength range is only possible if several diffraction gratings are being combined. Accordingly, the manufacturing of color sensors, multi-spectral sensors or spectrometers calls for combining several spectral optical sensors having different diffraction gratings.

Image sensors are further known. The U.S. Patent Application US2003/0103150 (Catrysse et al.) describes solutions for detecting a color by means of image sensors. One uses therefor patterned metal films for optical filtration of incident light. This light is converted into an electric signal by means of a detector. Next, this signal serves for reproducing the color for imaging purposes.

It is the object of the present invention to provide a spectral optical sensor, a method of manufacturing a spectral optical sensor, the use of a spectral optical sensor and a spectrometer for detecting various spectral information and/or polarizations.

Further, the spectral components of light to be detected should be analyzable by means of a spectral optical sensor.

The solution to this object is achieved by means of a spectral optical sensor for determining the spectral information with at least one optoelectronic semiconductor arrangement and at least one metal film, which is surrounded by a dielectric, wherein the metal film has a periodic pattern, wherein the at least one optoelectronic semiconductor arrangement and the at least one patterned metal film are arranged in such a way that light to be detected initially passes through the patterned metal film and then impinges on the optoelectronic semiconductor arrangement, wherein the spectral optical sensor is formed in such a way that the spectral sensitivity is determined essentially by the optical properties of the patterned metal film.

The optoelectronic semiconductor arrangement may either be determined by the optical properties of the patterned metal film only or other properties of the spectral optical sensor, beside the optical properties of the patterned metal film, may also contribute to the spectral sensitivity of the semiconductor arrangement. Further, the optical properties of the patterned metal film, which, together with the surrounding dielectric, may be referred to as a photonic crystal, may be determined by the formation of surface plasmons only, or other features of the spectral optical sensor, beside the formation of surface plasmons, may contribute to the optical properties of the photonic crystal. The spectral sensitivity is for example an electric signal which is tapped at the semiconductor arrangement and which is used as the detector signal of incident light.

In a preferred embodiment, the spectral optical sensor comprises several patterned metal films disposed one behind the other. Consecutive patterned metal films are substantially evenly spaced by the dielectric and a filter characteristic may be allocated to each patterned metal film. The light to be detected passes first through the metal films disposed one behind the other and is reflected therefrom to then impinge on the optoelectronic semiconductor arrangement.

It is preferred that electrodes are associated with the optoelectronic semiconductor arrangement, at least one of the electrodes being a component part of the patterned metal film. The at least one of the electrodes thus performs a double function. On the one side, it is associated with the optoelectronic semiconductor arrangement, and on the other side it forms a constituent part of the patterned metal or of the photonic crystal. This allows for more compact and simpler structure of the spectral optical sensor. This further has the advantage that, if several such type spectral optical sensors are disposed in a side-by-side relationship, the probability of what is referred to as Pixel Cross Talk is reduced since the distance between the optoelectronic semiconductor arrangement and the photonic crystal is minimized by virtue of this arrangement.

It is further preferred that the at least one of the electrodes forms a metallic photonic crystal together with the semiconductor layers which surround the at least one of the electrodes. Through such an arrangement, the spectral optical sensor can be made even more compact and smaller. In particular, such an arrangement, in which the semiconductor and metal layers form both part of the metallic photonic crystal (patterned metal films) and of the optoelectronic semiconductor arrangement, can be manufactured in one manufacturing process.

It is preferred that the at least one optoelectronic semiconductor arrangement forms a diode arrangement or a CCD device. Such an optoelectronic semiconductor arrangement can be readily manufactured using known semiconductor technologies, which are used for example to manufacture CCDs (Charge Coupled Devices) or CMOS (Complementary Metal Oxide Semiconductor) sensors.

According to another preferred embodiment, the at least one of the patterned metal films comprises holes and/or slots and/or depressions and/or nanodots. More specifically, the depressions are trenches. The formation of holes and/or slots and/or depressions and/or nanodots allows for purposefully adjusting the optical properties of the particularly metallic photonic crystal and to adapt them to certain requirements.

It is preferred that the holes and/or slots and/or depressions and/or nanodots are made using a lithographic method. With a lithographic method, the holes and/or slots and/or depressions and/or nanodots can be made very precisely, in a simple way and at low cost.

It is further preferred that the optical properties of the at least one photonic crystal are configured such that optical diffraction of the light of a given spectral range passing through the at least one photonic crystal does not substantially influence the optical properties of the photonic crystal. Accordingly, an in particular metallic photonic crystal behaves similar to an optical band-pass filter, whereas a diffraction-limited pattern behaves like an optical edge filter.

It is further preferred that the at least one photonic crystal is dimensioned such that the spectral optical sensor has a given spectral sensitivity. With a photonic crystal having such dimensions only certain spectral portions are detected by the optoelectronic semiconductor arrangement so that the spectral optical sensor only detects light of given wavelengths. This makes it possible to utilize the spectral optical sensor as an optical spectrometer or as a color sensor for example.

It is further preferred that the at least one photonic crystal is dimensioned such that the spectral optical sensor has a given polarization sensitivity. Such a configuration of the photonic crystal makes it possible to provide a spectral optical sensor that only detects light having a given polarization. The spectral optical sensor may therefore act as a polarization sensor.

According to another preferred embodiment, the spectral optical sensor is manufactured using a CCD, a CMOS (Complementary Metal Oxide Semiconductor) and/or a BiCMOS (Bipolar Complementary Metal Oxide Semiconductor) method.

These methods are known, mature and easy to carry out so that the spectral optical sensor is easy to manufacture.

It is further preferred that several patterned metal films are arranged proximate to each other, in particular one above the other, in such a manner that light to be detected passes first through the photonic crystals arranged proximate to each other, in particular one above the other, and then impinges on the optoelectronic semiconductor arrangement. Since each patterned metal film transmits or reflects light of a given spectral range and/or of a given polarization range, spectral optical sensors having any predetermined spectral sensitivity and/or polarization sensitivity may be manufactured by combining several such type photonic crystals.

It is further preferred that the spectral optical sensor comprises dielectric adaptation layers to adapt the spectral optical sensor to light to be detected. Through the adaptation layers, light to be detected is in particular better coupled into the photonic crystal. The dielectric adaptation layers may further be configured such that incident light, which is not to be detected by said spectral optical sensor, will not enter the photonic crystal. Through such type dielectric adaptation layers, the spectral sensitivity and/or polarization sensitivity of the spectral optical sensor can be further improved. As a result, a given spectral sensitivity may be achieved.

The object mentioned herein above is further achieved by a method of manufacturing a spectral optical sensor having at least one optoelectronic semiconductor arrangement and at least one patterned metal film, wherein the at least one optoelectronic semiconductor arrangement and the at least one patterned metal film are arranged such that light to be detected passes first through the patterned metal film or is reflected therefrom and then impinges on the optoelectronic semiconductor arrangement, and at least one patterned metal film is additionally configured to be an electrode and wherein said spectral optical sensor is configured such that the spectral sensitivity is essentially determined by the optical properties of the patterned metal film.

Preferably, at least one photonic crystal is provided with holes and/or slots and/or depressions and/or nanodots in order to set the optical properties of the photonic crystal and, as a result thereof, of the spectral optical sensor.

The holes and/or slots and/or depressions and/or nanodots are preferably made using a lithographic method. The spectral optical sensor is further preferably made using a CCD, a CMOS and/or a BiCMOS method. These methods are mature, reliable, easy and at low cost to perform.

The invention is further achieved by a spectral sensor for detecting spectral information and/or polarizations with a plurality of spectral optical sensors of the invention, at least some spectral optical sensors of said plurality of spectral optical sensors having different spectral sensitivity and/or polarization sensitivity. Using said plurality of spectral optical sensors, it is possible to manufacture a spectral sensor that reliably detects different spectral ranges and/or polarizations of incident light and may be utilized more readily than known spectral sensors for detecting different spectral ranges by virtue of the band-pass filter properties of the in particular metallic photonic crystal.

It is preferred that the spectral optical sensors of the plurality of spectral optical sensors having different spectral sensitivity and/or polarization sensitivity are made in one manufacturing process. The manufacturing of the spectral optical sensors in one semiconductor manufacturing process simplifies the manufacturing of the spectral sensors for detecting different spectral ranges and/or polarization conditions.

The plurality of spectral optical sensors preferably forms an arrangement that may be used as the optical spectrometer. Further, the spectral optical sensors of the plurality of spectral optical sensors are preferably combined to form a color sensor, several color sensors being preferably combined to form a one- or a two-dimensional arrangement in order to form a Line sensor or an image sensor. Using spectral optical sensors of the invention, such type arrangements and such type color sensors as optical spectrometers or image sensors may be simply realized at low cost. Further, the spectral sensitivity is improved over known arrangements and color sensors by virtue of the band-pass filter properties of the photonic crystals. Moreover, the polarization sensitivity of the spectral sensor can be set purposefully.

The object mentioned herein above is additionally achieved with a method of manufacturing a spectral sensor for detecting different spectral ranges, wherein a plurality of spectral optical sensors of the invention are combined, at least some spectral optical sensors of said plurality of spectral optical sensors having different spectral sensitivities and/or polarization sensitivities. It is preferred that said spectral optical sensors of said plurality of spectral optical sensors having different spectral sensitivities and/or polarization sensitivities are made in a semiconductor manufacturing process.

Embodiments of the present invention will be described herein after with reference to a drawing. In said drawing:

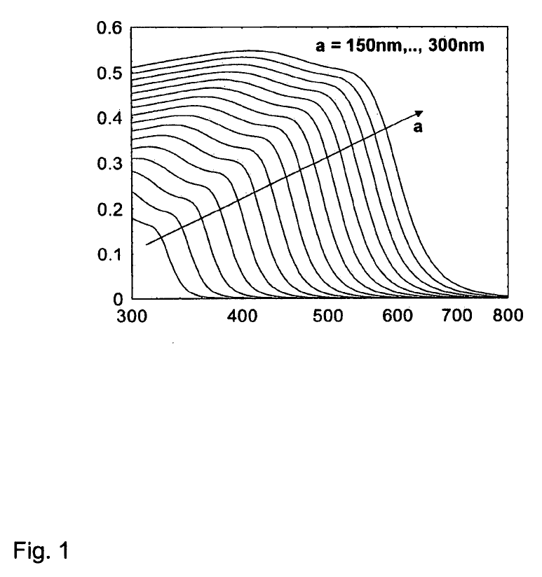

FIG. 1 illustrates the normalized optical transmission of a diffraction grating as a function of the wavelength in nanometers, the gap width a of the diffraction grating being varied from 150 nm to 300 nm in 10 nm steps. The transmission is respectively normalized to the surface area of a period of the diffraction grating. In this case, the period is 550 nm.

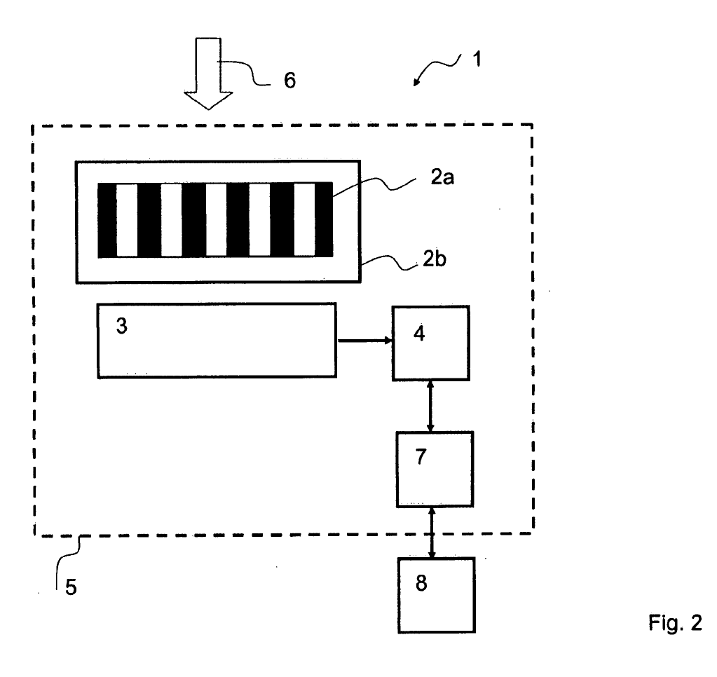

FIG. 2 shows a schematic view of an embodiment of the invention of a spectral optical sensor,

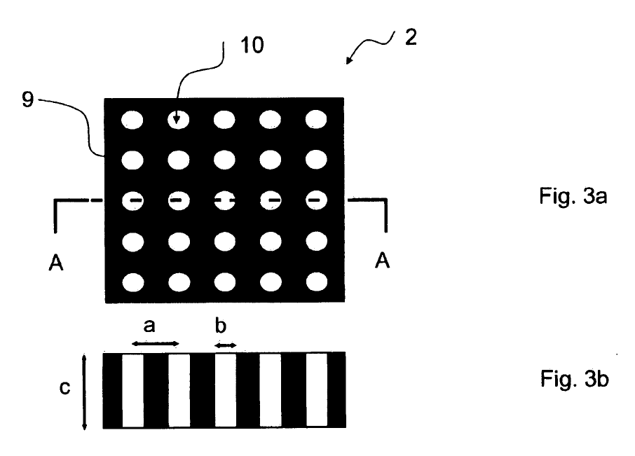

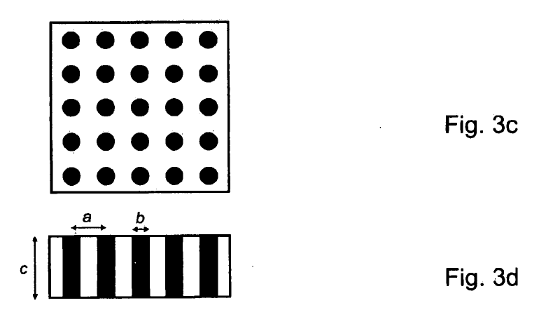

FIG. 3a shows a schematic top view of a patterned metal film with holes,

FIG. 3b shows a schematic sectional view of the metal film, taken along line A-A in FIG. 3a,

FIG. 3c shows a schematic top view of a nanodot-patterned metal film,

FIG. 3d shows a schematic sectional view of the metal film taken along line A-A in FIG. 3c,

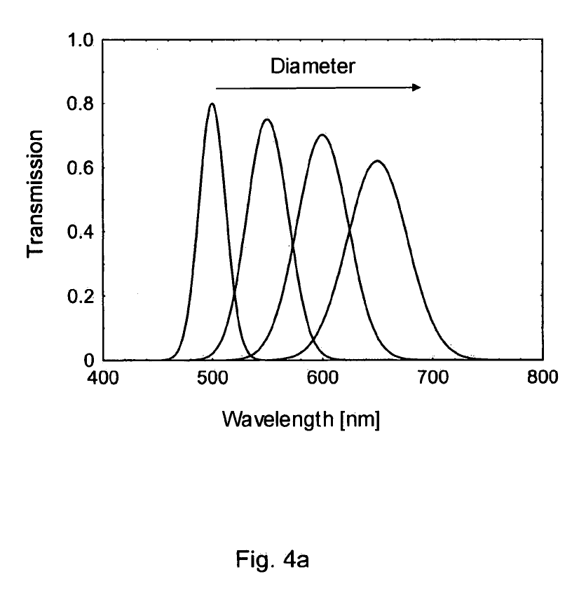

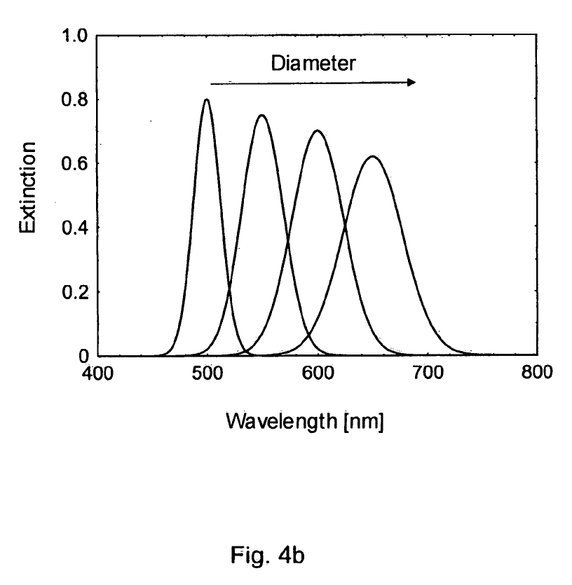

FIG. 4a shows the normalized optical transmission of a periodic hole array as a function of the wavelength in nanometers, the distance (from hole center to hole center) between the holes having been varied from 575 nm to 675 nm and the optical transmission having been respectively normalized to the surface area of the hole array,

FIG. 4b shows the normalized optical extinction of a periodic nanodot array as a function of the wavelength in nanometers, the distance (from nanodot to nanodot) between the nanodots having been varied from 575 nm to 675 nm and the optical extinction having been respectively normalized to the surface area of the nanodot array,

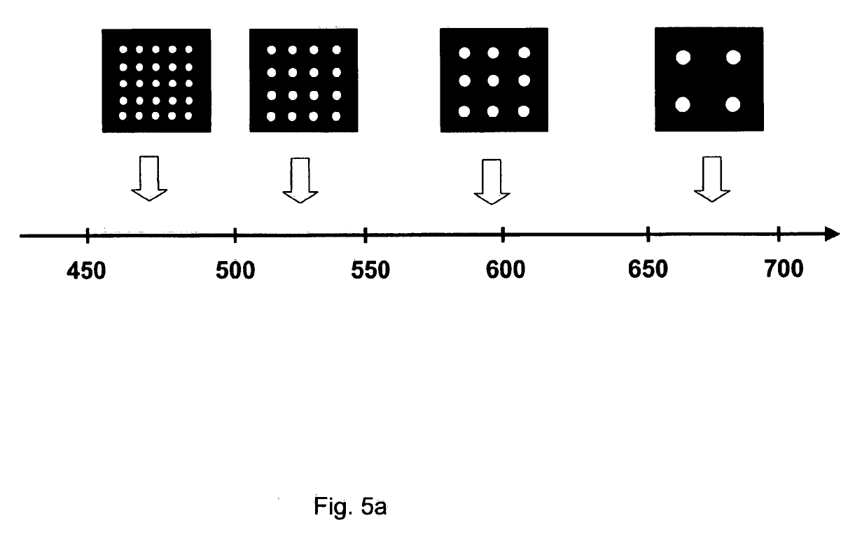

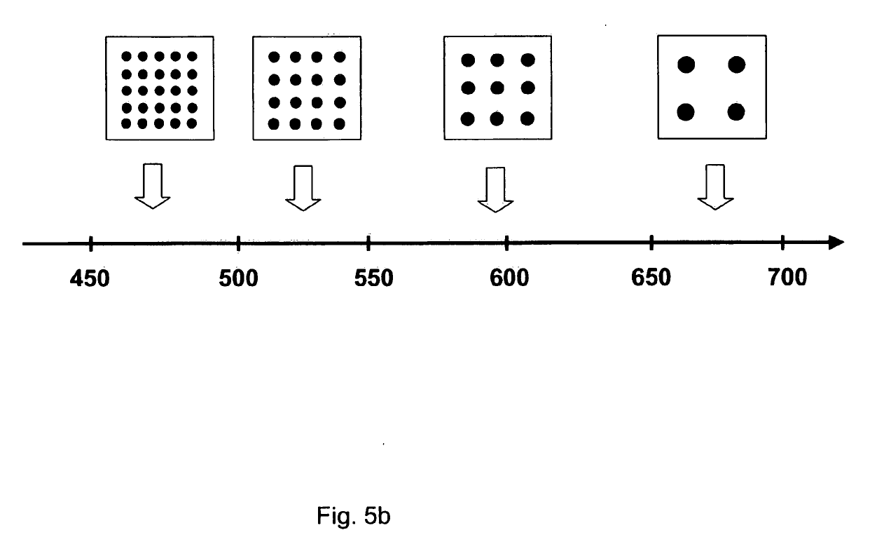

FIG. 5a shows an illustration of the cohesion between the design of a hole array and the optical properties of a hole array,

FIG. 5b shows an illustration of the cohesion between the design of a nanodot array and the optical properties of a nanodot array,

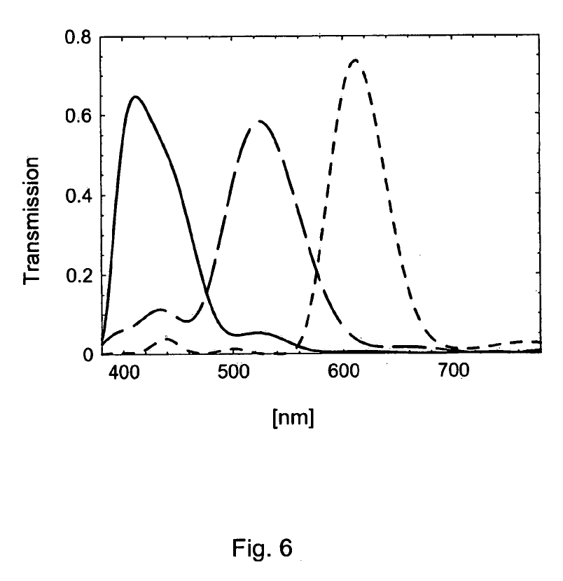

FIG. 6 shows the transmission of patterned metal films, said patterned metal films being optimized for use as optical filters for the colors red, green and blue,

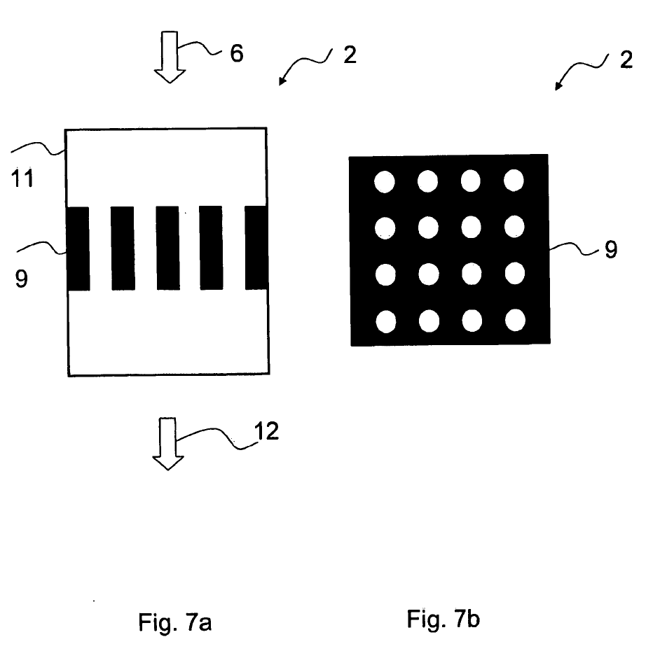

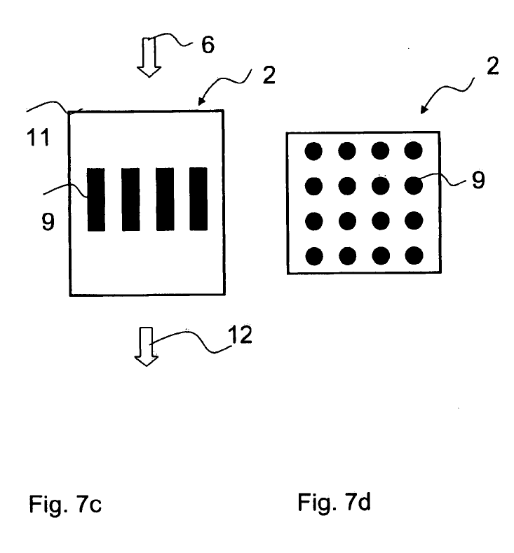

FIG. 7a shows a schematic side view of a hole-patterned metal film,

FIG. 7b shows a schematic top view of the hole-patterned metal film,

FIG. 7c shows a schematic side view of a nanodot-patterned metal film,

FIG. 7d shows a schematic top view of the nanodot-patterned metal film,

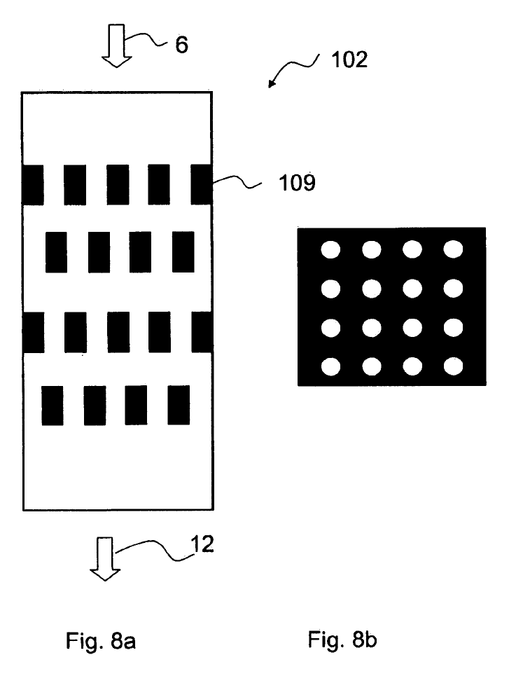

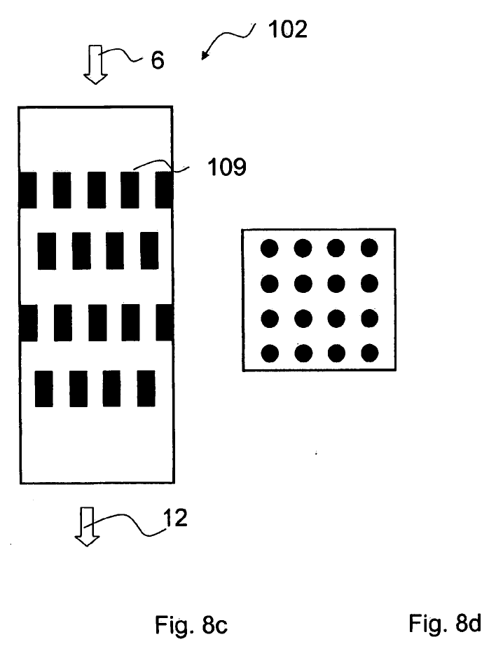

FIG. 8a shows a schematic side view of several patterned metal films disposed one above the other,

FIG. 8b shows a schematic top view of a hole-patterned metal film,

FIG. 8c shows a schematic side view of several patterned metal films disposed one above the other,

FIG. 8d shows a schematic top view of a nanodot-patterned metal film,

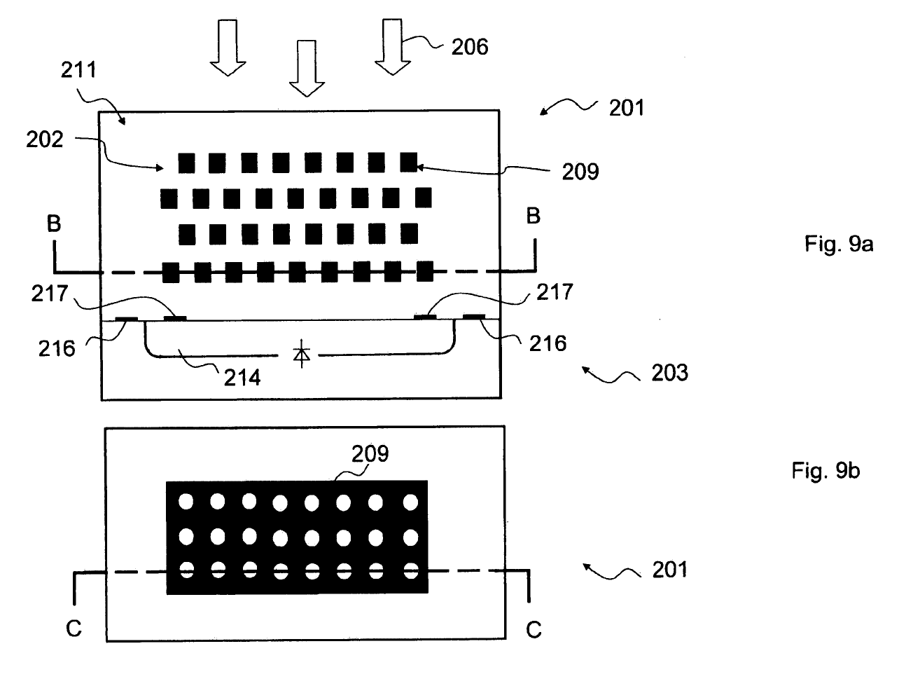

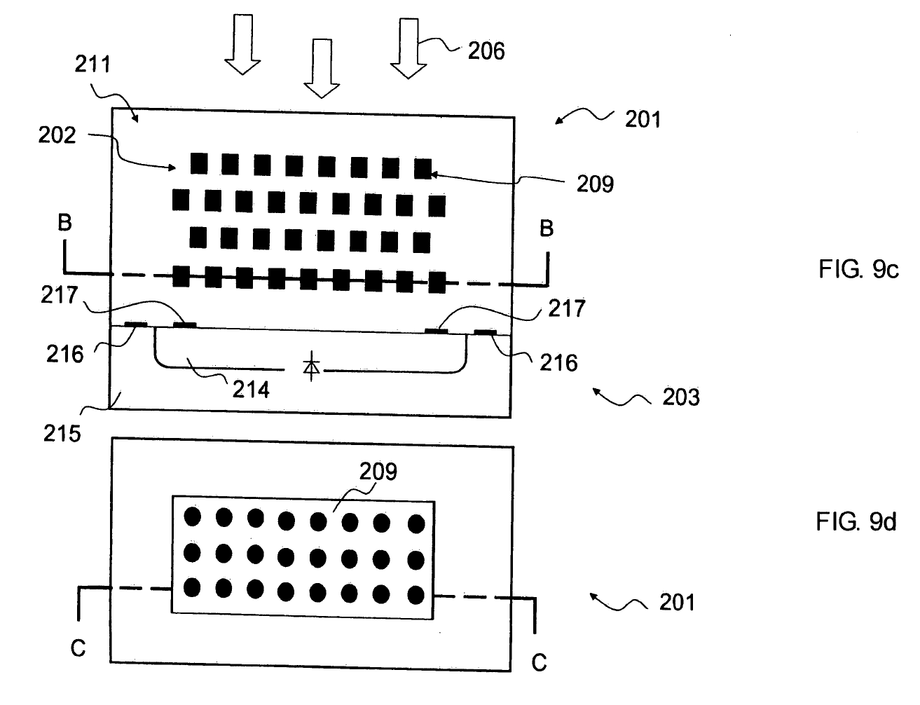

FIG. 9a shows a schematic sectional side view of a patterned metal film and of an optoelectronic semiconductor arrangement of a spectral optical sensor, taken along the line C-C in FIG. 9b,

FIG. 9b shows a schematic sectional view of the spectral optical sensor, taken along line B-B in FIG. 9a,

FIG. 9c shows a schematic sectional side view of a patterned metal film and of an optoelectronic semiconductor arrangement of a spectral optical sensor taken along line C-C in FIG. 9d,

FIG. 9b shows a schematic sectional view of the spectral optical sensor with nanodots, taken along line B-B in FIG. 9c,

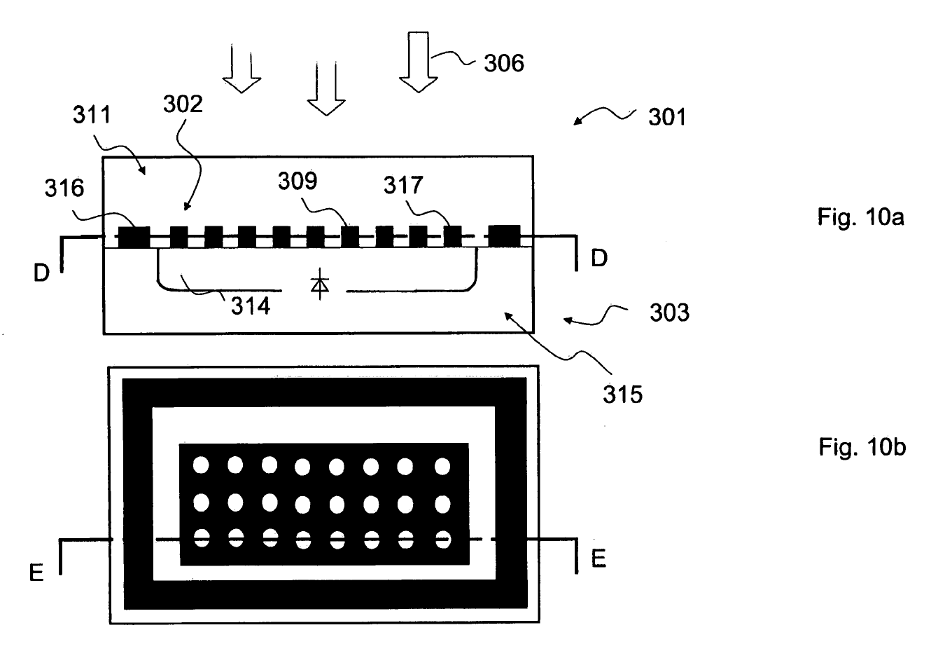

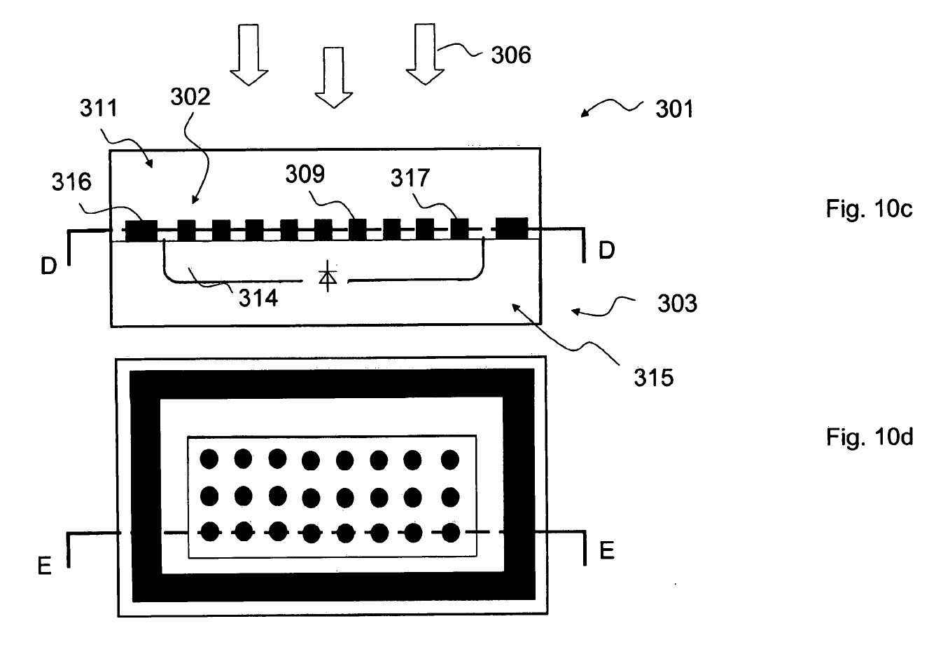

FIG. 10a shows a schematic sectional side view of another spectral optical sensor with a patterned metal film and an optoelectronic semiconductor arrangement, taken along line E-E in FIG. 10b,

FIG. 10b shows a schematic sectional view of the spectral optical sensor, taken along line D-D in FIG. 10a,

FIG. 10c shows a schematic sectional side view of another spectral optical sensor with a patterned metal film and of an optoelectronic semiconductor arrangement, taken along line E-E in FIG. 10d,

FIG. 10d shows a schematic sectional view of the spectral optical sensor with nanodots, taken along line D-D in FIG. 10c,

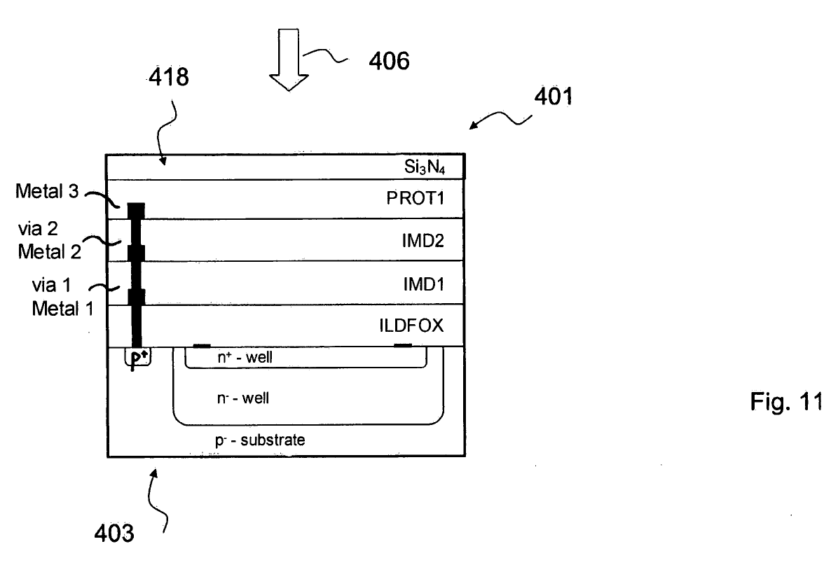

FIG. 11 shows a schematic view of a layered structure of a known spectral optical sensor using an optoelectronic semiconductor arrangement,

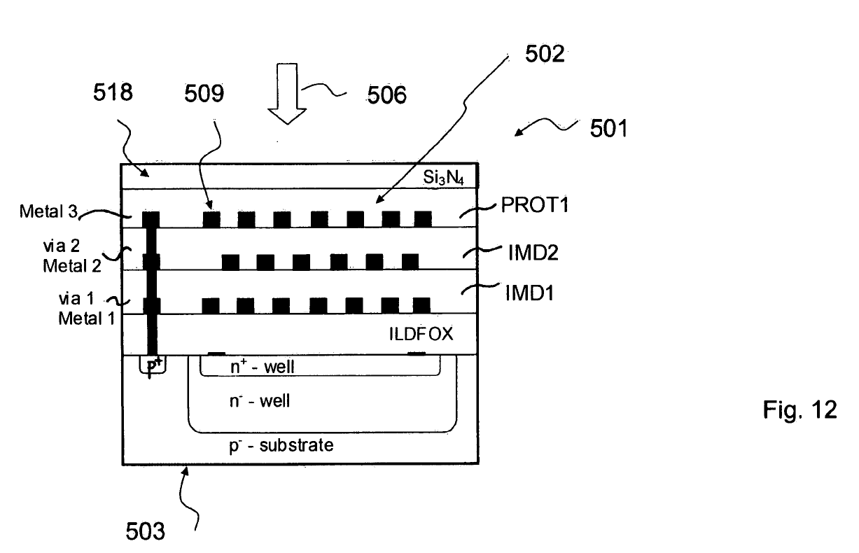

FIG. 12 shows a schematic view of a layered structure of a spectral optical sensor of the invention,

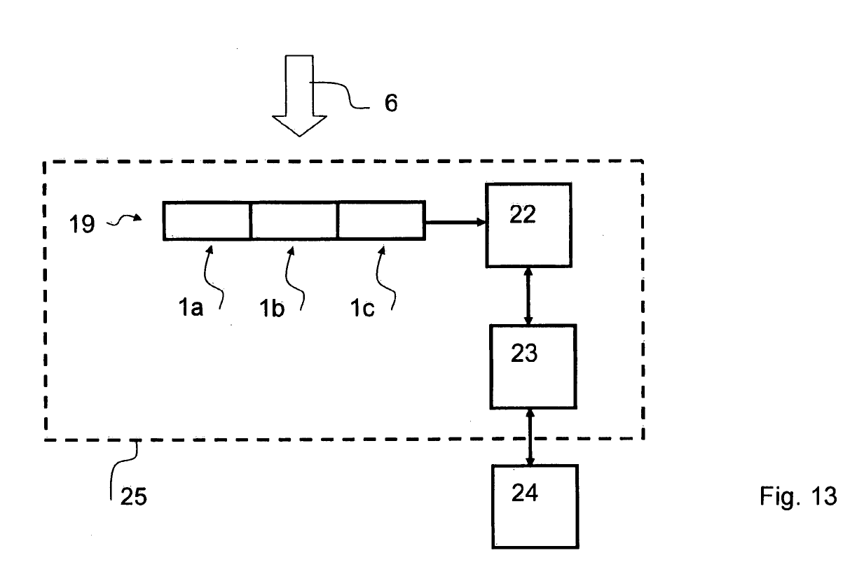

FIG. 13 shows a schematic illustration of a spectral sensor for detecting different wavelengths and/or polarizations,

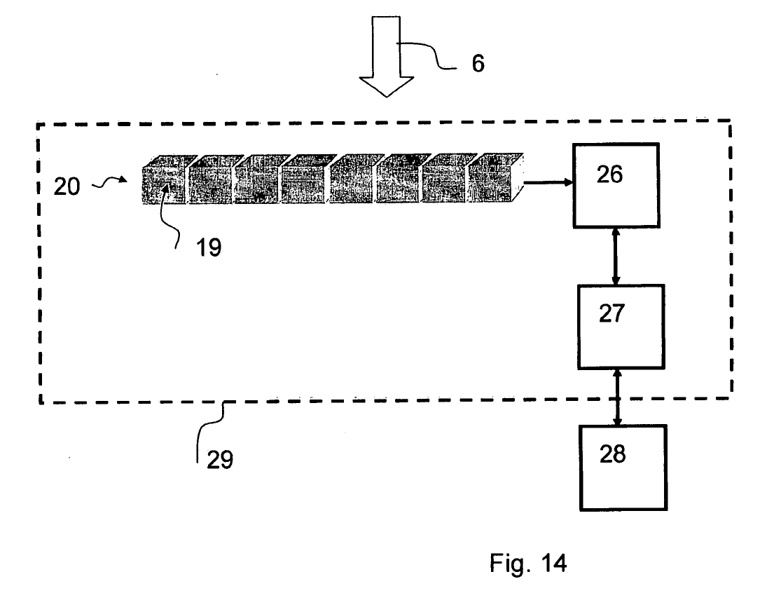

FIG. 14 shows a schematic view of a line sensor and

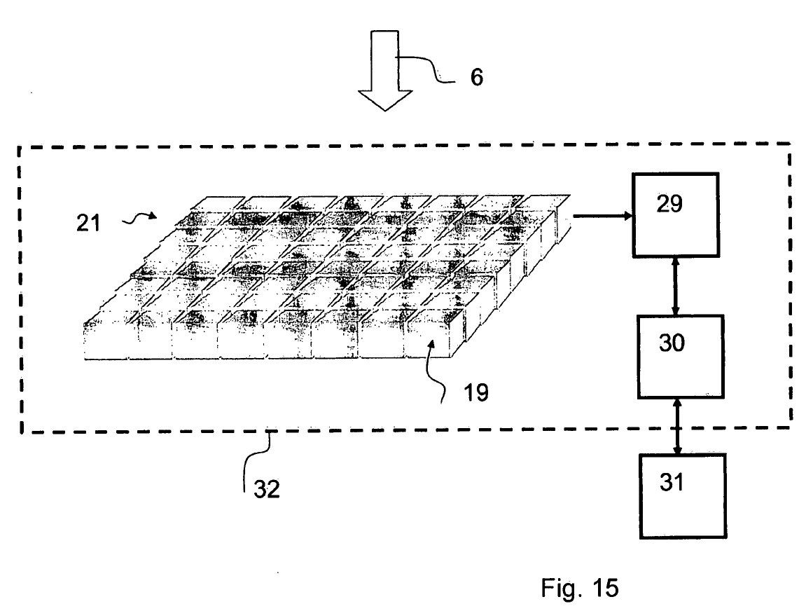

FIG. 15 shows a schematic view of an image sensor,

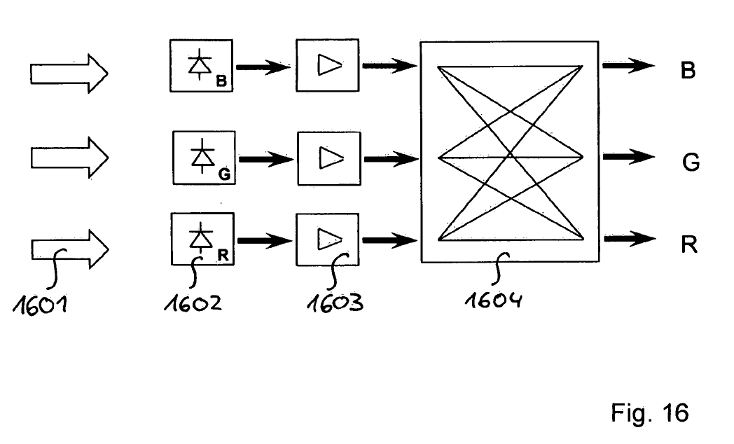

FIG. 16 shows a realization of a color sensor,

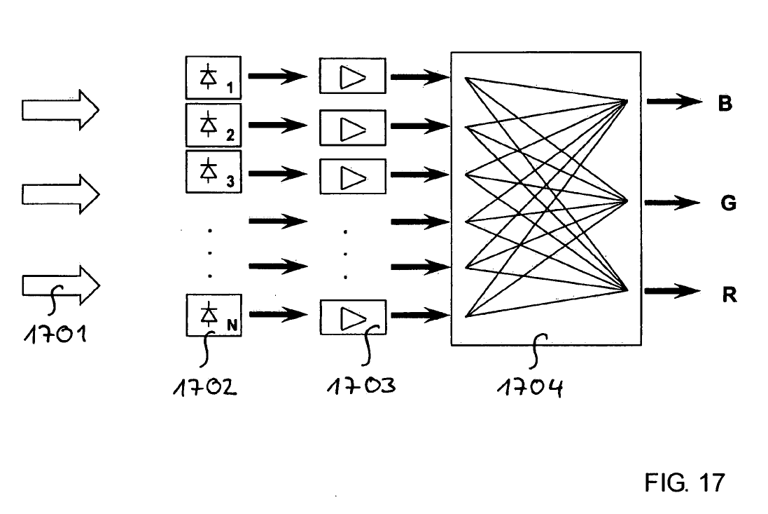

FIG. 17 shows a realization of a line sensor or of an image sensor.

FIG. 1 shows the normalized optical transmission of a diffraction grating as a function of the wavelength in nanometers, the gap width a of the diffraction grating having been varied from 150 nm to 300 nm in 10 nm steps. The transmission is respectively normalized to the surface area of a period of the diffraction grating. In this case, the period is 550 nm. The optical properties of the diffraction grating are determined by the optical refraction at the gap. For wavelengths of less than 2·a·n, wherein n is the index of refraction in the gap region, the light is allowed to pass through the optical diffraction grating. Light with a wavelength of more than 2·a·n is not allowed to pass through the diffraction grating. The diffraction grating behaves like an optical edge filter.

FIG. 2 shows a schematic view of a spectral optical sensor 1 having patterned metal films 2 disposed on top of each other (also referred to as a photonic crystal consisting of a metallic periodic pattern 2a and of a dielectric medium 2b; the term of photonic crystal will be used herein after as a synonym for a patterned metal film consisting of several layers spaced by a dielectric) and an optoelectronic semiconductor arrangement 3. The optoelectronic semiconductor arrangement 3 is connected to an amplifier 4 such as a current or voltage amplifier. The photonic crystal 2a, 2b and the optoelectronic semiconductor arrangement 3 are part of an integrated semiconductor circuit 5. Light impinges on the photonic crystal before it impinges on the optoelectronic semiconductor arrangement. The optoelectronic semiconductor arrangement 3 detects the light transmitted by the photonic crystal 2a, 2b. The optoelectronic semiconductor arrangement converts the detected light into electric signals and passes said signals to an amplifier 4. Said amplifier passes said electric signals to a processing unit 7. The amplifier 4 and the processing unit 7 are part of the integrated semiconductor circuit. The processing unit passes the signals to an external unit 8 which is an external evaluation or processing unit such as a computer.

The photonic crystal has a periodic pattern 2a and a dielectric medium 2b. In this embodiment, the periodic pattern is formed by a metal film 2a that is shown schematically in a top view in FIG. 3a. In the orientation shown in FIG. 3a, the light 6 would substantially strike the metal film 2a at right angles to the plane of the sheet. The metal film has a periodic arrangement of holes (hole array) 10 that are preferably configured to be circular.

FIG. 3b schematically shows a sectional view through the metal film 2a, taken along the line A-A shown in FIG. 3a.

The metal film 2a illustrated in the FIGS. 3a and 3b is surrounded by a dielectric medium 2b. Said dielectric medium may e.g., be air, silicon oxide and/or silicon nitride. Together with the dielectric medium 2b, the metal film 2a shown in the FIGS. 3a and 3b therefore forms a metallic photonic crystal.

The optical properties of the photonic crystal can be purposefully set through the shape of the holes, the diameter of the holes, the thickness of the metal film and the arrangement of the holes. Further, the optical properties of the metallic photonic crystal are determined by the complex index of refraction of the dielectric medium 2b, which surrounds the metal film. The dielectric material may for example be air, silicon oxide and/or silicon nitride, as already mentioned herein above. Further, the optical properties of the photonic crystal are influenced by the complex index of refraction of the metal, a preferred choice for the metal being aluminum, copper or gold.

Since the light 6 strikes the photonic crystal 2a, 2b, surface plasmons, which influence the transmission of incident light 6 through the photonic crystal 2a, 2b, form in proximity to the surface of the metal film 2a.

In the FIGS. 3c and 3d, nanodots have been used instead of holes. Referring to FIG. 3c, the comments are analogous to those referring to 3a and referring to FIG. 3d, the comments are analogous to 3b.

How the transmission of incident light is influenced by the properties of the photonic crystal 2 will now be described by way of example with reference to FIG. 4. In FIG. 4, the transmission of incident light normalized to the surface area of the hole array is plotted in nanometers against the wavelength λ. The various curves designate different photonic crystals, which comprise a gold film each. Said gold films are surrounded by air (dielectric medium). The photonic crystals differ by the distance a of the holes with respect to each other. The distance a between the holes is defined as the distance between the centers of neighboring holes, as shown in FIG. 3b. The distance between the holes was hereby increased from 575 nm to 675 nm.

From FIG. 4a it can be seen that the transmission peak shifts to higher wavelengths as the distance a increases. The wavelength λₘₐₓ of the transmission peak of the photonic crystal can be described with the following relation in a first approximation:

$${λ}_{max} ( i , j ) = \frac{a}{\sqrt{{i}^{2} + {j}^{2}} } \cdot \frac{\sqrt{{ɛ}_{1} \cdot {ɛ}_{2}}}{\sqrt{{ɛ}_{1} \cdot {ɛ}_{2}}} \qquad ( 1 )$$

wherein i and j represent the modes of the light. Further, ε₁ designates the dielectric constant of the metal and ε₂, the dielectric constant of the dielectric material.

Surface plasmons only form in materials with negative permittivity. Negative permittivity only occurs for metallic and metal oxide films. A preferred choice for metals with negative permittivity is gold, silver, copper and aluminum.

Rather than holes, the photonic crystal can also comprise other periodic patterns such as slots or depressions, in particular trenches or nanodots, which may be elongate in shape.

The metal film has a preferred thickness c of 200 nm. The preferred diameter b of the holes is 250 nm. By varying the diameter of the holes, the spectral range in which the surface plasmons form can be shifted. The transmission peaks shift for example to shorter wavelengths as the diameter of the holes decreases. The reverse occurs as the diameter of the holes increases. The transmission peaks shift to longer wavelengths as the diameter increases.

The comments referring to FIG. 4a apply in analogous fashion to 4b, where the extinction is plotted against the wavelength. This applies in the event that the photonic crystal has been patterned by means of nanodots.

FIG. 5a shows the schematic cohesion between the design of a hole array and the transmission properties as a function of the wavelength in nanometers. For the purpose of manufacturing a metallic photonic crystal comprising an optical transmission peak in the blue spectral range (about 450 nm), holes having a small diameter and being spaced a small distance apart are to be made in the film. Assuming that the metal film is an aluminum film surrounded by a silicon oxide, one obtains a transmission peak in the blue range with a hole diameter of 130 nm and a spacing between the holes of 250 nm. If one increases the diameter of the holes and their spacing, the transmission peak shifts to higher wavelengths. One then obtains a transmission peak in the green spectral range for a hole diameter of 155 nm and for a spacing between the holes of 400 nm. In FIG. 5b, the same is shown for nanodot patterned photonic crystals.

FIG. 6 shows the transmission for different metallic photonic crystals that have been optimized for use as optical filters. The transmission is plotted as a function of the wavelength in nanometers. A hole array was made in a respective 200 nm thick aluminum film. The hole array is embedded in a film made of silicon oxide. The transmission peak in the blue spectral range (about 450 nm) is obtained for a hole diameter of 130 nm and for a spacing between the holes of 250 nm (continuous line). The transmission peak in the green spectral range (about 550 nm) is obtained for a hole diameter of 155 nm and for a spacing of 400 nm (long dash line). The transmission peak in the red spectral range (600 nm-650 nm) is obtained for a hole diameter of 180 nm and for a spacing of 520 nm (short dash line).

FIG. 7a shows a schematic side view of a photonic crystal 2 with a metal film 2a and a dielectric medium 2b that surrounds the metal film 2a. Incident light 6 enters into the dielectric 2b and strikes the metal film 2a with the periodic pattern. When light falls on the metal film, surface plasmons form in proximity to the surface of the metal film. The surface plasmons propagate in the metal film. Accordingly, the surface plasmons can propagate through the holes in the metal film. On the side of the metal film on which light exits, the surface plasmons interfere. The light 12 transmitted through the photonic crystal 2 impinges on the optoelectronic semiconductor arrangement 3, which detects the transmitted light 12. In FIG. 7b, there is illustrated a schematic top view of the photonic crystal 2. This applies in corresponding fashion in the event that nanodots are used instead of holes. This is illustrated in the FIGS. 7c and 7d, the comments referring to 7a applying in analogous fashion to 7c and the comments referring to 7b in analogous fashion to 7d.

Beside the use of individual metal layers 2a with holes, more complex patterns can be utilized to influence the wave propagation of incident light. A photonic crystal 102 having a more complex pattern is illustrated in a schematic side view in the FIGS. 8a and 8c (nanodots).

The photonic crystal 102 comprises several metal films 109 disposed behind each other in the direction of irradiation. Each of these metal films 109 has a periodic pattern, in particular a periodic hole pattern. Each metal film 109 can be sized differently so that each metal film 109 influences differently the incident light 6. FIG. 8b shows a schematic top view of one of said metal films 109 of the photonic crystal 102. According to FIG. 8d, a schematic top view shows one of these metal films with nanodots 109 of the photonic crystal 102.

Since each metal film 109 is surrounded by the dielectric, each of said metal films 109 can be considered a discrete photonic crystal. In this sense, FIG. 8a shows several photonic crystals, which are disposed one behind the other in the direction of incident light 6.

The photonic crystal can be made in particular by means of optical lithography, which is also utilized for manufacturing micro- and nanoelectronic integrated semiconductor circuits. Accordingly, the metallic photonic crystals can be readily combined with optoelectronic components such as diodes. The diode is an optoelectric semiconductor arrangement, by means of which the light transmitted through the photonic crystal can be detected. With a spectral optical sensor comprising a combination consisting of a photonic crystal and of a diode arrangement

as the optoelectronic semiconductor arrangement, the spectral sensitivity of the spectral optical sensor can be set purposefully. Such type spectral optical sensors can be utilized for example in high-resolution image sensors, color sensors, multi-spectral sensors or spectrometers. Such a spectral optical sensor, which comprises a combination of a photonic crystal and of a diode arrangement as the optoelectronic semiconductor arrangement, is illustrated in the FIGS. 9a, 9b, 9c and 9d.

FIG. 9a and accordingly 9c are a schematic sectional side view of a spectral optical sensor 201. The spectral optical sensor 201 comprises several metal films 209 disposed one behind the other in the direction of incident light 206. The metal films 209 are surrounded by a dielectric medium 211 so that the discrete metal films 209, which are each surrounded by the dielectric medium 211, form together with the surrounding dielectric medium a photonic crystal. Therefore, several photonic crystals 202 are disposed one behind the other in the direction of incident light 206 in FIG. 9a/9c. The spectral optical sensor 201 further comprises an optoelectronic semiconductor arrangement 203. The optoelectronic semiconductor arrangement 203 comprises an n-doped range 214 and a p-doped range 215. The n-doped range 214 is preferably formed from phosphorus- or arsenic-doped silicon and the p-doped range 215 is preferably formed from boron-doped silicon. The n-doped range 214 and the p-doped range 215 are arranged such that the n-doped range 214 is disposed first and the p-doped range 215 behind in the direction of incident light 206. The transition between the n-doped range 214 and the p-doped range 215 forms a diode arrangement that acts as a photodiode. The optoelectronic semiconductor arrangement 203 is provided with electrodes 216, 217. The n-doped range 214 forms a well-like pattern with a U-shaped cross section. The well-like pattern is embedded in the p-doped range 215. The electrode 216 is preferably disposed on the edge of the well-like pattern of the p-doped range 215. The electrode 217, by contrast, is preferably disposed on the n-doped range 214 in the shape of a rectangular or circular border.

Incident light 206 passes through the metal films 209, which comprise a periodic pattern, in particular a periodic hole pattern. In the metal films 209, which are surrounded by the dielectric medium 211, surface plasmons are excited to form by virtue of incident light 206. The light, which is influenced by the surface plasmons which are forming, finally falls on the optoelectronic semiconductor arrangement 203 and in particular on the transition between the n-doped range 214 and the p-doped range 215. In the transition range, charge carriers forming a photocurrent are generated in a known way, said photocurrent being tapped in a known way by means of the electrodes 216, 217. The corresponding electric signals are transmitted to the evaluation unit 4 for evaluation.

FIG. 9b is a schematic sectional view of the spectral optical sensor 201 taken along the line B-B in FIG. 9a. In this sectional view, the periodic pattern of a metal film 209 can be seen.

The holes in the metal films 209 are preferably significantly smaller than the wavelength of the light to be detected. Since visible light in particular is to be detected by the spectral optical sensor 201, the diameter of the holes is preferably significantly smaller than the wavelength of visible light. The diameter of the holes in the metal film is preferably smaller than λ/2/n, wherein λ is the wavelength of incident light 206 and n the index of refraction of the dielectric medium 211. Assuming that the visible spectral range to be detected comprises a wavelength range of 380 nm to 680 nm, one obtains a hole diameter of the metal films 209 that is smaller than 130 nm if the index of refraction is n=1.5 (index of refraction of silicon oxide). The transmission obtained with such type metal films 209, which are surrounded by the dielectric medium, is only influenced by surface plasmons in the above mentioned visible wavelength range (see FIG. 6 in this context). In this spectral range, the diffraction of light has no influence on the optical properties of the photonic crystal 201. These comments apply in analogous fashion to FIG. 9d, wherein the patterning incorporates nanodots.

FIG. 10a/10c shows a schematic sectional side view of another embodiment of the invention of a spectral optical sensor 301. FIG. 10b shows a schematic sectional view of the spectral optical sensor 301, viewed in the direction of incident light 306. The sectional view in FIG. 10b illustrates a section taken along line D-D in FIG. 10a and the sectional view in FIG. 10a a sectional view taken along line E-E in FIG. 10b. The comments to FIG. 10b apply in analogous fashion to 10d, wherein nanodots are utilized for patterning.

The spectral optical sensor 301 comprises a metal film 309 that is provided with a periodic hole pattern (hole array) and that is surrounded by a dielectric medium 311. Further, said spectral optical sensor 301 comprises an optoelectronic semiconductor arrangement 303 incorporating an n-doped range 314 and a p-doped range 315. The n-doped range 314 and the p-doped range 315 are arranged such that the n-doped range 314 is disposed first and the p-doped range 315 behind in the direction of incident light 306.

The transition between the n-doped range 314 and the p-doped range 315 forms, as already described herein above, a diode arrangement that is used as a photodiode. The electric signals of the optoelectronic semiconductor arrangement 303, that is, of the photodiode, are tapped by means of electrodes 316, 317. The electrode 316 is disposed on the p-doped range 315 of the optoelectronic semiconductor arrangement 303. The electrode 317 is formed by the metal film 309 that is disposed directly on the n-doped range 314 of the optoelectronic semiconductor arrangement 303.

The p-doped range 315 preferably forms a block, in particular a cuboid block, which has a well-like depression in which there is disposed the n-doped range 314. The electrode 316 is preferably disposed on the edge of the well-like p-doped range 315 that is turned toward incident light.

The metal film 309 performs a double function. On the one side, it serves to control the propagation of incident light. On the other side, the metal film 309 serves as an electrode 317 for the diode arrangement. This combination of several functions simplifies the structure of the spectral optical sensor 301. Moreover, the spacing between the optoelectronic semiconductor arrangement 303 and the photonic crystal 302, which is formed by the metal film 309 and by the dielectric medium 311 surrounding the metal film 309, is minimized. As a result, what is referred to as Pixel Cross Talk, which occurs with conventional spectral optical sensors, is prevented.

Photonic crystals of the invention can be manufactured by means of classical silicon semiconductor technologies. This includes for example semiconductor processes, which are used to manufacture CCDs or CMOS sensors.

FIG. 11 schematically shows the layered structure of a conventional spectral optical sensor in CMOS silicon technology. The spectral optical sensor 401 comprises the following layer sequence as the photodiode: p⁻ substrate, n⁻ well and n⁺ well. This layer sequence forms an optoelectronic semiconductor arrangement 403. Above said optoelectronic semiconductor arrangement there are located several dielectric layers. On a conventional spectral optical sensor, these layers serve as the “window layer”. Light passes through these light without being absorbed in these dielectric layers. This is shown in FIG. 11. The spectral optical sensor 401 includes an antireflection coating 418 which preferably comprises Si₃N₄. The antireflection coating 418 is preferably anti-reflective to light to be detected, in particular to light in the visible spectral range.

The n⁺ well is preferably a highly phosphorus- or arsenic doped well. The n⁻ well is preferably a low phosphorus- or arsenic doped well. The p⁺ well is preferably a low boron-doped well. Further, PROT1 in FIG. 11 designates a protective layer, IMD2 and IMD1 respectively a silicon oxide layer which are made by wet chemical techniques and are embedded between two metal levels and ILDFOX designates a silicon oxide intermediate layer, which is made by wet chemical techniques. Further, in FIG. 11 the terms “via 1” and “via 2” designate an opening or a hole in the IMD1 and the IMD 2 respectively. The terms “metal 1”, “metal 2” and “metal 3” each designate a metal level.

FIG. 12 schematically shows the layered structure of an embodiment of a spectral optical sensor 501 of the invention. The spectral optical sensor 501 differs from the conventional sensor 401 shown in FIG. 11 by the metal films 509. Together with the dielectric medium surrounding the metal films 509 the metal films 509 form photonic crystals 502. The optoelectronic semiconductor arrangement is formed by the following layer sequence, like with the conventional spectral optical sensor shown in FIG. 11: p⁻ substrate, n⁻ well and n⁺ well. In another manufacturing step, a dielectric layer ILDFOX is deposited onto the semiconductor arrangement. The vias (through penetrations) are then made in this layer. Next, these vias are filled with metal. For the purpose of connecting the through penetrations, another metal layer is deposited, which is patterned by means of optical lithography. Likewise, the metal layer can be used for manufacturing the metallic periodic pattern of a metallic photonic crystal. Incident light 506 passes through the anti-reflection coating 518 and through the photonic crystals 502. In the photonic crystals 502, surface plasmons form, which influence incident light 506. The light transmitted by the photonic crystals 502 is detected by the optoelectronic semiconductor arrangement 503, electric signals being generated, which are evaluated by the evaluation unit 4.

As compared to the manufacturing of the conventional sensor 401, the manufacturing of the spectral optical sensor 501 of the invention needs no additional method step so that known semiconductor methods can be made use of to manufacture the photonic crystal of the invention. Thus, the metallic periodic patterns can be made together with the metallic bond lines of an integrated semiconductor circuit. The metallic bonds of the various components are hereby standard elements of each semiconductor process. The metal bonds are structured by means of optical lithography. It is possible to manufacture the periodic metallic patterns in the same work step.

The optoelectronic semiconductor arrangement preferably comprises silicon, but it can comprise, instead or additionally, germanium, gallium arsenide, gallium nitride, indium phosphate or amorphous silicon.

FIG. 13 shows a schematic view of a spectral sensor 19 for detecting different wavelengths and/or polarizations, said sensor comprising several spectral optical sensors 1a, 1b, 1c of the invention. The spectral sensor 19 for detecting different wavelengths and/or polarizations comprises in particular three different spectral optical sensors 1a, 1b, 1c of the invention. The photonic crystals of the spectral optical sensors 1a, 1b, 1c are adapted to have different wavelength sensitivities and/or polarization sensitivities. Different wavelength sensitivities may for example be achieved in that the metal films of the photonic crystals comprise different spacings between the holes and/or different hole diameters. The photonic crystals of the spectral optical sensors 1a, 1b, 1c are adapted for each spectral optical sensor 1a, 1b, 1c to detect another spectral range. In particular, the spectral optical sensors 1a, 1b, 1c may be adapted for each spectral optical sensor to only detect one certain color, such as red, blue and green. The spectral sensor 19 for detecting different wavelengths and/or polarizations is in particular connected to a current or voltage amplifier 22 that amplifies the electric signals of the spectral optical sensors 1a, 1b, 1c, i.e., the optoelectronic response of the semiconductor arrangements, so that they may be processed in another step. This processing unit 23 also establishes the connection with another external processing and output device 24. The processing electronics 23 serves inter alia to convert the amplified sensor signals (analogous signals) into digital signals. Further, the digital signals are processed so that they can be passed to an external processing electronics 24. The processing electronics 24 ensures the communication between the spectral optical sensor and other electronic apparatus such as a computer or a storage medium for storing the image/sensor information.

If, as shown in FIG. 13, the spectral sensor element 19 for detecting different wavelengths and/or polarizations comprises three spectral optical sensors 1a, 1b, 1c of the invention, this spectral sensor 19 preferably forms a color sensor. If the spectral sensor element 19 for detecting different wavelengths and/or polarizations comprises more than three spectral optical sensors of the invention having different wavelength sensitivities, the spectral sensor 19 preferably forms a multi-spectral sensor. If the spectral sensor element 19 for detecting different wavelengths and/or polarizations comprises a plurality of spectral optical sensors of the invention having different wavelength sensitivities and if the evaluation unit 24 reconstructs the spectrum of incident light 6 and of the electric signals of the spectral optical sensors 1a, 1b, 1c, this spectral sensor 19 preferably forms a spectrometer.

For the spectral optical sensors 1a, 1b, 1c to comprise different polarization sensitivities, the holes of the metal films of the different spectral optical sensors 1a, 1b, 1c can have different shapes. Transmission through a photonic crystal for example is dependent on polarization if the holes have no circular cross section but a rectangular one, the two sides of the rectangle having different lengths. The lengths of the sides of the rectangle, which forms the cross section of the respective hole, can be selected for light of an imposed polarization to pass the photonic crystals. These lengths can be adapted to desired polarization-dependent transmissions through calibration for example.

FIG. 14 is a schematic view of a line sensor 20 that comprises several color sensors 19. This line sensor 20 is also connected to an amplifier 26, a processing and evaluation unit 27 and an external output or processing unit 28. The line sensor 20, the amplifier 26 and the processing and evaluation unit 27 are integrated in a semiconductor circuit 29. Thanks to the line sensor 20 a location information can be detected beside the color information of incident light 6. In this case also, the processing electronics 27 serves to convert the amplified sensor signals (analogous signals) into digital signals. Further, the digital signals are processed so that they can be passed to an external processing electronics 28. The processing electronics 27 ensures the communication between the spectral optical sensor and other electronic apparatus such as a computer or a storage medium for storing the image/sensor information.

FIG. 15 shows a schematic view of an image sensor 21 that comprises a two-dimensional arrangement of the color sensors 19. The image sensor 21 is also equipped with one or several amplifiers 33, which amplify the electric signals of the spectral sensor. Then, the signals are processed in a processing unit 30 and are passed to an external evaluation unit 31. The image sensor 21, the amplifier or the amplifiers 33 and the processing and evaluation unit 30 are integrated in a semiconductor circuit 32. By means of the image sensor 21, two-dimensional location information can be detected beside the color information. The processing electronics 30 serves in this case as well to convert the amplified spectral sensor signals (analogous signals) into digital signals. Further, the digital signals are processed so that they can be passed to an external processing electronics 31. The processing electronics 31 ensures the communication between the spectral optical sensor and other electronic apparatus such as a computer or a storage medium for storing the image/sensor information.

FIG. 16 illustrates a color sensor. The light 1601 is thereby converted into a color system serving for display by means of three spectral sensors that are associated with a certain spectrum. Such a color system is for example the TV color system used for color broadcasting (RED, GREEN, BLUE are labeled at R, G and B), by means of which the visible color spectrum can be reproduced by superposition. One of the three spectral sensors 1602 thereby filters RED, one GREEN and the other one BLUE. Their signal is processed by means of the processing electronics 1603 and is associated with a value for RED, GREEN and BLUE by means of color processing unit 1604. As a result, an image sensor is realized which can reproduce the visible impressions.

FIG. 17 illustrates a line sensor. Advantageously, one acquires here additional spatial information. Incident light 1701 is filtered through the spectral sensors 1702 (1 . . . N). Then, the filtered spectral sensor signal is processed by the processing electronics 1703 and is next associated with the color values by the color processing unit 1704. The number of the spectral sensor is thereby additionally communicated so that one then has spatial-spectral information.

By means of known semiconductor manufacturing methods, such as by means of photolithographic methods, spectral optical sensors having different wavelengths and/or polarization sensitivities can be manufactured. This allows for simple and easy manufacturing of color sensors for example. Known color sensors by contrast use absorption filters, every single filter for red, green and blue having to be applied separately, which leads to the complex manufacturing process of conventional color sensors. This advantage of the invention is even more obvious in the field of multi-spectral technique, which deals with the most precise possible detection of the optical spectrum of incident light. Usually, a plurality of sensor channels, that is to say of spectral optical sensors, is needed hereby. The integration of this plurality of spectral optical sensors comprising different absorption filters is very complex and expensive. By means of conventional semiconductor manufacturing methods, spectral sensors for detecting different wavelengths and/or polarizations comprising several spectral optical sensors can be manufactured in one manufacturing process, which simplifies the manufacturing of such type spectral sensors, in particular in the field of multi-spectral technique.

What matters for the manufacturing of the spectral sensors is the manufacturing of the different metallic photonic crystals. As already illustrated in the FIGS. 4-6, the optical properties of the metallic photonic crystal may be set purposefully inter alia by the diameters and the spacing between the holes of a hole array. The hole arrays can be made by optical lithography. Therefore, spectral sensors with different spectral sensitivity can be manufactured in one work step. This is obvious from FIG. 5. The diameter and the spacing between the holes of the metallic photonic crystal are hereby dictated by the dimensions of the lithographic mask.

As already mentioned herein above, optical filters are used on known spectral optical sensors in order to generate desired wavelength selectivity, said filters being spaced some micrometers apart from the actual optoelectronic semiconductor arrangement. If such type spectral optical sensors are now disposed in a line or in planar fashion, what is referred to as Pixel Cross Talk occurs due to the quite large spacing between the respective optical filter and the spectral optical sensor. This means that light passing a certain optical filter will not strike or not only strike the associated optoelectronic semiconductor arrangement but the optoelectronic semiconductor arrangement of the neighboring spectral optical sensor. As a result, the spatial resolution of known line sensors and image sensors is reduced. In accordance with the invention, the spacing between the photonic crystal and the optoelectronic semiconductor arrangement can be reduced so that the Pixel Cross Talk is strongly reduced over known line sensors and image sensors. Further, the metal film of the photonic crystal can be disposed directly on the optoelectronic semiconductor arrangement so that Pixel Cross Talk is even completely prevented as a result thereof.

Further, as already described herein above, known line sensors and image sensors use absorption filters in order to selectively detect light wavelengths. However, as compared to photonic crystals, the properties of such absorption filters can only be set in a certain range, narrow-band absorption filters for example can only be manufactured at very great expense. The optical properties of photonic crystals by contrast can be set purposefully and simply, as described herein above.

Although a component part of the photonic crystal has been referred to as a metal film, the invention is not limited to certain metal film thicknesses. The metal film may also have a thickness greater or smaller than the 200 nm mentioned herein above.

The amplifiers and evaluation units mentioned in the specification process the electric signals received by the spectral optical sensors of the invention in a known way so that the respective color and/or intensity and/or location and/or polarization information can be passed to an output unit.

Beside the use of optical lithography, the metal films can also be patterned by means of focused ion beams for example. Holes having a diameter of less than 100 nm can be made by means of focused ion beams, the metal films being preferably thicker than 100 nm.

The adaptation of spectral optical sensors to desired optical properties is not limited to the adaptation of the above mentioned features of the spectral optical sensor, such as the hole diameter of the photonic crystal or the index of refraction of the dielectric. In accordance with the invention, each feature of the spectral optical sensor which contributes to the optical properties of the spectral optical sensor can be configured such that the spectral optical sensor comprises desired optical properties.

The spectral sensitivity of the spectral sensors can be set purposefully substantially by varying the size, the shape and the arrangement of the holes and/or depressions and/or slots, and/or nanodots.

This allows for realizing color sensors consisting of three spectral sensors. The objective is to reproduce human color perception. Human color perception is described by the normalized spectral curves.

Now, the goal of the development or of the optimization of a color sensor is to reproduce these normalized spectral curves. On the one side, this occurs by adapting the spectral sensitivity of the spectral sensors. Moreover, mathematical methods (color processing) can also be utilized to improve the color signals.

A line sensor or image sensor now consists of a plurality of such color sensors. The spectral resolution of a color sensor is however not sufficient for a plurality of applications. For example to control paints in the automotive industry or to control products in the printing industry. Spectrometers are utilized therefor. Further, such spectrometers can be utilized to monitor the degree of ripeness or the decay of fruit or to detect skin cancer. Existing spectrometer solutions however are often too expensive to manufacture. The approach proposed herein allows for a very low-cost manufacturing of spectrometers.

By varying the nano-patterned metal film of the spectral sensors, the complete optical spectrum can be scanned with high spectral resolution. For this purpose, 15-20 spectral sensors are needed, depending on the spectral sensitivity of the sensors.

The sensor signals can be processed like with an image sensor. The color aberration of the thus obtained color signals RGB is however much lower.

1. A spectral optical sensor for determining spectral information of incident light, in particular in the visible and infrared spectral range having at least one optoelectronic semiconductor arrangement and at least one metal film, which is surrounded by a dielectric, said metal film comprising a periodic pattern, wherein the at least one optoelectronic semiconductor arrangement and the at least one patterned metal film are arranged in such a way that light to be detected first passes the patterned metal film and then impinges on the optoelectronic semiconductor arrangement, said spectral optical sensor being configured such that the spectral sensitivity is essentially determined by the optical properties of the patterned metal film.

2. The spectral optical sensor as set forth in claim 1, wherein several patterned metal films are disposed one after the other in such a manner that consecutive patterned metal films are substantially evenly spaced by the dielectric and that light to be detected first passes through the metal films disposed one behind the other or is reflected therefrom and then impinges on the optoelectronic semiconductor arrangement.

3. The spectral optical sensor as set forth in claim 1, wherein electrodes are associated with the optoelectronic semiconductor arrangement, at least one of the electrodes being a constituent part of at least one patterned metal film.

4. The spectral optical sensor as set forth in claim 1, wherein the at least one optoelectronic semiconductor arrangement forms a diode arrangement or a CCD device.

5. The spectral optical sensor as set forth in claim 1, wherein the patterned metal film comprises holes and/or slots and/or depressions and/or nanodots.

6. The spectral optical sensor as set forth in claim 5, wherein the holes and/or slots and/or depressions and/or nanodots are made using a lithographic method.

7. The spectral optical sensor as set forth in claim 1, wherein the optical properties of the patterned metal film are configured such that optical diffraction of the light of a given wavelength range passing through the patterned metal film does not substantially influence the optical properties of the patterned metal film.

8. The spectral optical sensor as set forth in claim 1, wherein the patterned metal film is configured such that the spectral optical sensor has a given spectral sensitivity.

9. The spectral optical sensor as set forth in claim 1, wherein the patterned metal film is configured such that the spectral optical sensor has a given polarization sensitivity.

10. The spectral optical sensor as set forth in claim 1, wherein the spectral optical sensor is made using a CCD, a CMOS and/or a BiCMOS method.

11. A method of manufacturing a spectral optical sensor with at least one optoelectronic semiconductor arrangement and at least one patterned metal film, wherein said at least one optoelectronic semiconductor arrangement and said at least one patterned metal film are disposed such that light to be detected first passes through the patterned metal film or is reflected therefrom and then impinges on the optoelectronic semiconductor arrangement and at least one patterned metal film is additionally configured as an electrode and wherein the spectral optical sensor is configured such that spectral sensitivity is essentially determined by the optical properties of the patterned metal film.

12. The method as set forth in claim 11, wherein the patterned metal film is provided with holes and/or slots and/or depressions and/or nanodots.

13. The method as set forth in claim 12, wherein the holes and/or slots and/or depressions and/or nanodots are made using a lithographic method.

14. The method as set forth in claim 13, wherein the spectral optical sensor is made using a CCD, a CMOS and/or a BiCMOS method.

15. An arrangement for detecting spectral information and/or polarization with a plurality of spectral optical sensors, in particular a spectrometer, as set forth in claim 1, wherein at least some spectral optical sensors of said plurality of spectral optical sensors have different spectral sensitivities and/or polarization sensitivities.

16. The arrangement for detecting spectral information and/or polarizations, in particular a spectrometer, as set forth in claim 15, wherein the spectral optical sensors of said plurality of spectral optical sensors with different wavelength sensitivities and/or polarization sensitivities are made in one manufacturing process.

17. The arrangement for detecting spectral information and/or polarizations, in particular a spectrometer, as set forth in claim 15, wherein several spectral sensors of the plurality of spectral optical sensors are combined to form a color sensor.

18. The arrangement for detecting spectral information and/or polarizations, in particular a spectrometer, as set forth in claim 15, wherein several spectral sensors are formed in a one- or two- or three-dimensional arrangement in order to form a line sensor or an image sensor.

19. The arrangement for detecting spectral information and/or polarizations, in particular a spectrometer, as set forth in claim 15, wherein several spectral sensors are formed in a one- or two- or three-dimensional arrangement, the complete spectral curve of incident light being acquired by detecting spectral information.

20. Use of a spectral optical sensor as set forth in claim 1 for spectroscopy or in a spectrometer.
